(19) United States
(12) Patent Application Publication
(10) Pub. No.: US 2020/0306931 A1
(43) Pub. Date: Oct. 1, 2020

(54) METHODS AND APPARATUS FOR REMOVING ABRASIVE PARTICLES

(71) Applicant: APPLIED MATERIALS, INC., Santa Clara, CA (US)

(72) Inventors: PRAYUDI LIANTO, SINGAPORE (SG); PENG SUO, SINGAPORE (SG); SHIH-CHAO HUNG, SINGAPORE (SG); PIN GIAN GAN, SINGAPORE (SG); CHUN YU TO, SINGAPORE (SG); PERIYA GOPALAN, SAN JOSE, CA (US); KOK SEONG TEO, SINGAPORE (SG); LIT PING LAM, SINGAPORE (SG); ANDY LOO, SINGAPORE (SG); PANGYEN ONG, SINGAPORE (SG); DAVID P. SURDOCK, KALISPELL, MT (US); KEITH YPMA, Kalispell, MT (US); BRIAN WILLIAMS, Kalispell, MT (US); SCOTT OSTERMAN, Whitefish, MT (US); MARVIN L. BERNT, KALISPELL, MT (US); MUHAMMAD NORHAZWAN, SINGAPORE (SG); SAMUEL GOPINATH, SINGAPORE (SG); MUHAMMAD AZIM, SINGAPORE (SG); GUAN HUEI SEE, SINGAPORE (SG); QI JIE PENG, SINGAPORE (SG); SRISKANTHARAJAH THIRUNAVUKARASU, SINGAPORE (SG); ARVIND SUNDARRAJAN, SINGAPORE (SG)

(21) Appl. No.: 16/363,009

(22) Filed: Mar. 25, 2019

(51) Int. Cl. B24B 57/00; H01L 21/02; B24B 37/34

(52) U.S. Cl. CPC B24B 57/00; B24B 37/34; H01L 21/02074

(57) ABSTRACT

Methods and apparatus for removing particles from a substrate surface after a chemical mechanical polish. In some embodiments, the apparatus may include a manifold configured to receive and atomize a fluid and at least one spray nozzle mounted to the manifold and configured to spray the atomized fluid in a divergent spray pattern such that the substrate surface is cleansed when impinged by spray from the at least one spray nozzle, wherein the at least one spray nozzle sprays the atomized fluid at a pressure of approximately 30 psi to approximately 2500 psi.

### FIELD

Embodiments of the present principles generally relate to semiconductor processing.

### BACKGROUND

In order to provide a smooth, even surface on a substrate during semiconductor processing, a chemical mechanical planarization or chemical mechanical polishing (CMP) tool may be used to abrade the surface of the substrate to polish out any imperfections. A slurry of abrasive materials are used to aid in the rotational polishing motion of the CMP tool. After the polishing has been completed, the substrate is cleaned to remove the remaining slurry from the substrate surfaces. However, the inventors have observed that as the size of the semiconductor structures shrink, not all of the abrasive particles are removed with the current cleaning methods. When particles remain in the semiconductor structures, the defects often cause catastrophic failures of the semiconductor device. Accordingly, the inventors have provided improved methods and apparatus for removing particles from a substrate surface.

### SUMMARY

Methods and apparatus for removing particles from surfaces of a substrate are provided herein.

In some embodiments, an apparatus for removing particles from a substrate surface after a chemical mechanical polish may comprise a manifold configured to receive and atomize a fluid and at least one spray nozzle mounted to the manifold and configured to spray the atomized fluid in a divergent spray pattern such that the substrate surface is cleansed when impinged by spray from the at least one spray nozzle.

In some embodiments, the apparatus may further include wherein the fluid is deionized (DI) water, wherein the at least one spray nozzle sprays the atomized fluid at a pressure of approximately 30 psi to approximately 2500 psi, wherein the at least one spray nozzle sprays the atomized fluid at a pressure of approximately 1000 psi to approximately 1500 psi, wherein the manifold further receives a gas to facilitate in atomizing the fluid, wherein the gas is nitrogen gas, wherein the at least one spray nozzle has a spray opening of greater than zero to approximately 1 mm, wherein the at least one spray nozzle has a spray opening of greater than zero to approximately 0.5 mm, wherein the at least one spray nozzle has a fan-like or conical spray pattern, wherein the at least one spray nozzle has a spray pattern of less than or equal to approximately 120 degrees, wherein at least one of the at least one spray nozzle is a pulsed jet spray nozzle, wherein the pulsed jet spray nozzle is configured to operate at a frequency of approximately 400 kHz to approximately 3 MHz, wherein the at least one spray nozzle is a knife spray nozzle with a slit opening, and/or wherein the knife spray nozzle has a length approximately equal to a diameter of a substrate.

In some embodiments, an apparatus for removing particles from a substrate surface after a chemical mechanical polish may comprise a manifold that atomizes deionized (DI) water with nitrogen gas and at least one spray nozzle mounted to the manifold and configured to deliver the atomized DI water in a divergent spray pattern to cleanse the substrate surface when the substrate surface is impinged by spray from the at least one spray nozzle, wherein the at least one spray nozzle sprays the atomized fluid at a pressure of approximately 30 psi to approximately 2500 psi.

In some embodiments, the apparatus may further include wherein the at least one spray nozzle has a spray opening of greater than zero to approximately 1 mm with a fan-like or conical spray pattern of 120 degrees or less, wherein the at least one spray nozzle is a pulsed jet spray nozzle that is configured to operate at a frequency of approximately 400 kHz to approximately 3 MHz, and/or wherein the at least one spray nozzle is a knife spray nozzle with a slit opening having a length of approximately a diameter of a substrate.

In some embodiments, a system for chemical mechanical polishing a substrate surface may comprise a plurality of platens for polishing substrates; a plurality of spray apparatus for cleaning a surface of a substrate, the plurality of spray apparatus disposed between the plurality of platens, wherein at least one of the plurality of spray apparatus includes a manifold configured to atomize deionized (DI) water with nitrogen gas and at least one spray nozzle mounted to the manifold and configured to deliver the atomized DI water in a divergent spray pattern to cleanse the substrate surface when the substrate surface is impinged by spray the at least one spray nozzle, wherein the at least one spray nozzle sprays the atomized fluid at a pressure of approximately 30 psi to approximately 2500 psi, and a controller that interacts with at least one of the spray apparatus to alter a spray pattern of the at least one spray nozzle based on a substrate size or material composition of the substrate surface.

In some embodiments, the system may further comprise wherein the at least one spray nozzle has a spray opening of greater than zero to approximately 1mm with a fan-like or conical spray pattern of 120 degrees or less, wherein the at least one spray nozzle is a pulsed jet spray nozzle that is configured to operate at a frequency of approximately 400 kHz to approximately 3 MHz, and/or wherein the at least one spray nozzle is a knife spray nozzle with a slit opening having a length of approximately a diameter of a substrate.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method of removing particles from a substrate surface in accordance with some embodiments of the present principles.

FIG. 2 illustrates a chemical mechanical polishing (CMP) process in accordance with some embodiments of the present principles.

FIG. 3 is a top-down view of a CMP polishing module of a CMP system in accordance with some embodiments of the present principles.

FIG. 4 is a cross-sectional view of a CMP polishing station in accordance with some embodiments of the present principles.

FIG. 5 is a three-dimensional view of a spray apparatus in accordance with some embodiments of the present principles.

FIG. 6 is a three-dimensional view of another spray apparatus in accordance with some embodiments of the present principles.

FIG. 7 is a three-dimensional view of yet another spray apparatus in accordance with some embodiments of the present principles.

FIG. 8 is a cross-sectional view of spray nozzles in accordance with some embodiments of the present principles.

FIG. 9 is a three-dimensional view of a spray pattern in accordance with some embodiments of the present principles.

FIG. 10 is a three-dimensional view of a spray apparatus with a knife spray nozzle in accordance with some embodiments of the present principles.

FIG. 11 is a three-dimensional view of another spray apparatus with a knife spray nozzle in accordance with some embodiments of the present principles.

FIG. 12 is a top-down view of a knife spray nozzle in accordance with some embodiments of the present principles.

FIG. 13 is a cross-sectional view of a knife spray nozzle spray pattern in accordance with some embodiments of the present principles.

FIG. 14 is a cross-sectional view of a spray system in accordance with some embodiments of the present principles.

FIG. 15 is a cross-sectional view of a cleaner of a CMP tool in accordance with some embodiments of the present principles.

FIG. 16 is a cross-section view of spray nozzles in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and apparatus provide enhanced chemical mechanical polishing (CMP) processing in wafer-level packaging technology to meet the ever increasing denser interconnect requirements. During CMP processing, abrasive particles are introduced into openings on a substrate surface. The abrasive particles are particularly harmful on copper surfaces such as redistribution layers (RDL) found on polymer layers. The particles are trapped, especially in smaller openings such as vias, resulting in wafer yield loss and scaling roadblocks. The methods and apparatus of the present principles, in some embodiments, integrates a spray apparatus into the polishing module of the CMP system. The spray apparatus is interposed between platens of the polishing module and provides a high pressure, atomized spray that cleans the surface of the substrate as the substrate moves between polishing stations. In some embodiments, the spray apparatus is integrated into a CMP cleaner to provide a high pressure, atomized spray that cleans one or more surfaces of the substrate after chemical mechanical polishing. The integration of the spray apparatus into a CMP tool allows for enhanced particle removal from the surface of the substrate without interfering with the chemical mechanical polishing process, increasing yield while also saving time.

In some embodiments, more than one spray apparatus may be integrated into the polishing module so that cleaning can be performed between polishing stations or upon entry of the substrate to the polishing module or prior to exiting of the substrate out of the polishing module. In some embodiments, more than one spray apparatus may be integrated into the cleaner to enhance the throughput of the cleaner. In some embodiments, the spray apparatus uses an inert gas (e.g., nitrogen) or others (e.g., clean dry air (CDA)) to facilitate in atomizing a fluid, such as, but not limited to, deionized (DI) water and/or solvents and the like. In some embodiments, nitrogen gas may be used because nitrogen gas does not oxidize metals on the substrate that may lead to further contamination. In some embodiments, the spray apparatus may use spray nozzles with pulsing technology to atomize the fluid. In some embodiments the spray apparatus may use pressure alone to atomize the fluid. In some embodiments, the spray apparatus is advantageously flexible in providing a cleaning solution for particles from any size of substrate by allowing the control of the number of spray nozzles that are actively spraying without requiring hardware changes.

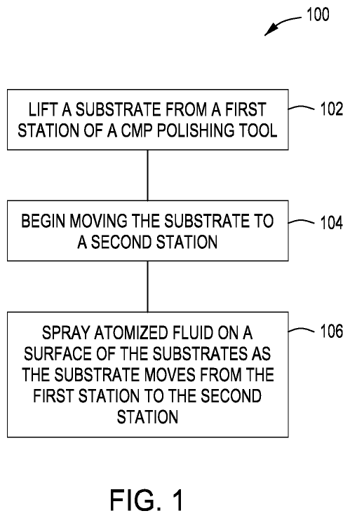

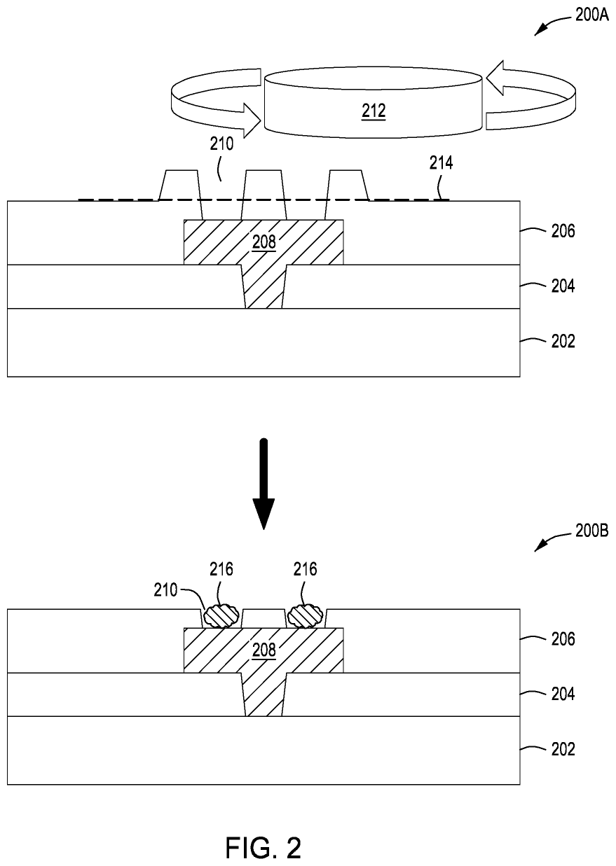

FIG. 1 is a method 100 of removing particles from a substrate surface. The method 100 references FIG. 2 which illustrates a CMP process. As shown in view 200A, a substrate 202 may have layers 204, 206 of, for example, polymer on the surface. A redistribution layer 208 may also be present as well as openings 210 in an upper layer 206 that expose the redistribution layer 208. A polishing pad 212 of a CMP tool abrades a surface 214 of the substrate to smooth the surface 214 for subsequent processing. As illustrated in view 200B, particles 216 are often left in the openings 210 which hamper the subsequent processing and may even cause failure of the structures on the substrate 202, lowering yields. In block 102, the substrate 202 is lifted from a first polishing station of the CMP tool. The polishing action along with the polishing slurry may have deposited particles 216 in openings 210 on the substrate 202. In block 104, the substrate 202 has begun to move to a second station of the CMP tool. As discussed in further detail below, a spray apparatus is positioned between the first and second polishing station of the CMP tool. As the substrate 202 is moved from the first station to the second polishing station, the substrate 202 will pass over the spray apparatus. In block 106, an atomized fluid is sprayed onto a surface of the substrate 202 as the substrate moves form the first station to the second polishing station. In some embodiments, the atomized fluid is sprayed on a surface of the substrate 202 when in the cleaner of the CMP tool. Because the particle cleaning process is integrated between the polishing stations of the CMP tool and/or in the cleaner of the CMP tool, the particle cleaning process may be performed without interrupting the normal process flow of the CMP tool, saving time and money.

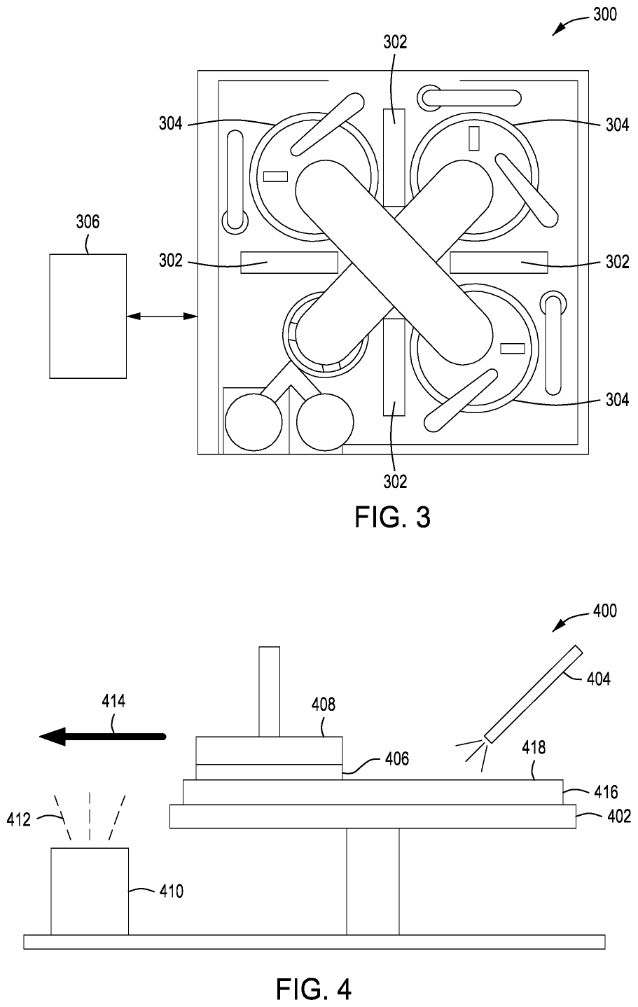

FIG. 3 is a top-down view of a CMP polishing module 300 of a CMP system. The CMP polishing module 300 includes a plurality of polishing stations 304. Interposed between the polishing stations 304 are spray apparatus 302 that clean the surface of the substrate as the substrate is moved from one polishing station 304 to the next and/or as the substrate is entering and/or exiting the CMP polishing module 300. The spray apparatus 302 is sized and positioned to spray the surface of the substrate as the substrate passes above the spray apparatus 302. In some embodiments, a controller 306 may interact with control of the spray apparatus 302. In some embodiments, the controller 306 may adjust a spray coverage (angular dispersion), spray pressure, and/or duration of the spray apparatus 302 based on a substrate size, substrate material, and/or a process parameter. In some embodiments, the controller 306 may increase or decrease a number of active spray nozzles of the spray apparatus 302 depending on a size of the substrate. By increasing or decreasing active spray nozzles, different diameter substrates may be cleaned without requiring hardware changes or process interruptions. In some embodiments, the controller 306 may activate or deactivate different versions of spray nozzles to enhance cleaning by the spray apparatus 302. In some embodiments, the controller 306 may change a type of gas supplied to the spray apparatus 302 based upon a substrate material and/or a process parameter.

FIG. 4 is a cross-sectional view of a polishing station 400 with a spray apparatus 410. The polishing station 400 includes a platen assembly 402 that supports a polishing pad 416 with a polishing surface 418. A polishing fluid delivery arm 404 provides a polishing slurry on the polishing surface 418. A carrier head 408 holds a substrate 406 such that the substrate surface to be polished is held downward. The polishing slurry may contain abrasive particles that may adhere inside openings on the polished surface of the substrate surface. The carrier head 408 lifts the substrate 406 off of the polishing surface 418 and moves the substrate 406 in direction 414 to a next polishing station or to an exit point. As the substrate 406 is moved, the substrate 406 passes over the spray apparatus 410, exposing the polished surface of the substrate 406 to an atomized fluid spray 412 provided by the spray apparatus 410. The spray pattern is such that at least a portion, if not all, of the polished surface of the substrate 406 is sprayed with the atomized fluid spray 412. The spray apparatus 410 may also be mounted in a cleaner 1500 of a CMP tool for cleaning of the substrate surfaces 1504 as shown in FIG. 15. In some embodiments, the spray apparatus 410 may be mounted in the cleaner 1500 in an overhead position. In some embodiments, the spray apparatus 410 may be mounted in the cleaner 1500 at a spray angle 1502 of less than or equal to approximately 90 degrees with respect to the substrate surfaces 1504.

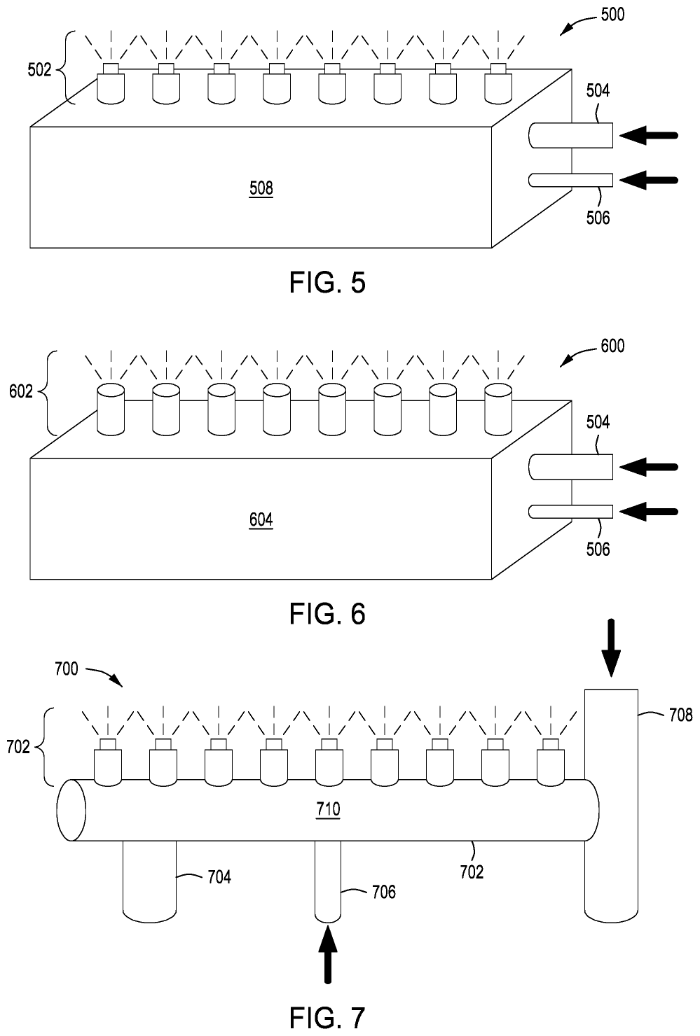

In FIG. 5, a three-dimensional view of a spray apparatus 500 is illustrated. The spray apparatus 500 may include a plurality of spray nozzles 502 mounted on an upper surface of a spray manifold 508. The spray nozzles 502 deliver an atomized fluid spray. The atomization may be obtained by injecting a gas along with a fluid. In some embodiments, the fluid may be supplied by a fluid supply line 504 and the gas may be supplied by a gas supply line 506. In some embodiments, the atomization is obtained by solely pressurizing the fluid, and the spray manifold 508 may only have a fluid supply line 504. In some embodiments, the number of the plurality of spray nozzles 502 is such that the spray pattern as a whole sprays an entire surface of a substrate as the substrate passes over the spray nozzles 502. The size of the spray pattern is dependent on the number of spray nozzles and the spray pattern of the individual spray nozzles.

In FIG. 6, a three-dimensional view of a spray apparatus 600 is shown. The spray apparatus 600 may include a plurality of spray nozzles 602 which may create ultrasonic and/or megasonic pulsed spray. The spray nozzles are mounted on an upper surface of a spray manifold 604. The atomization may be obtained by injecting a gas along with a fluid. In some embodiments, the fluid may be supplied by a fluid supply line 504 and the gas may be supplied by a gas supply line 506. In some embodiments, the atomization is obtained by solely pressurizing the fluid, and the spray manifold may only have a fluid supply line 504. The ultrasonic and/or megasonic pulses atomize a fluid provided to the spray nozzles via the fluid supply line 504. In some embodiments, the number of the plurality of spray nozzles 602 is such that the spray pattern as a whole sprays a portion, if not all, of a surface of a substrate as the substrate passes over the spray nozzles 602. The size of the spray pattern is dependent on the number of spray nozzles and the spray pattern of the individual spray nozzles.

In FIG. 7, a three-dimensional view of a spray apparatus 700 is depicted. In some embodiments, a spray manifold 710 with a cylindrical form may be used with spray nozzles 702 that provide atomization of a fluid either by pressure alone, gas and fluid combined, and/or ultrasonic and/or megasonic pulsing. In some embodiments, the spray manifold 710 may be supported by one or more supports 704, 708. In some embodiments, gas is supplied via gas supply line 706 and a fluid is supplied via support 708 acting as a support and a fluid supply line.

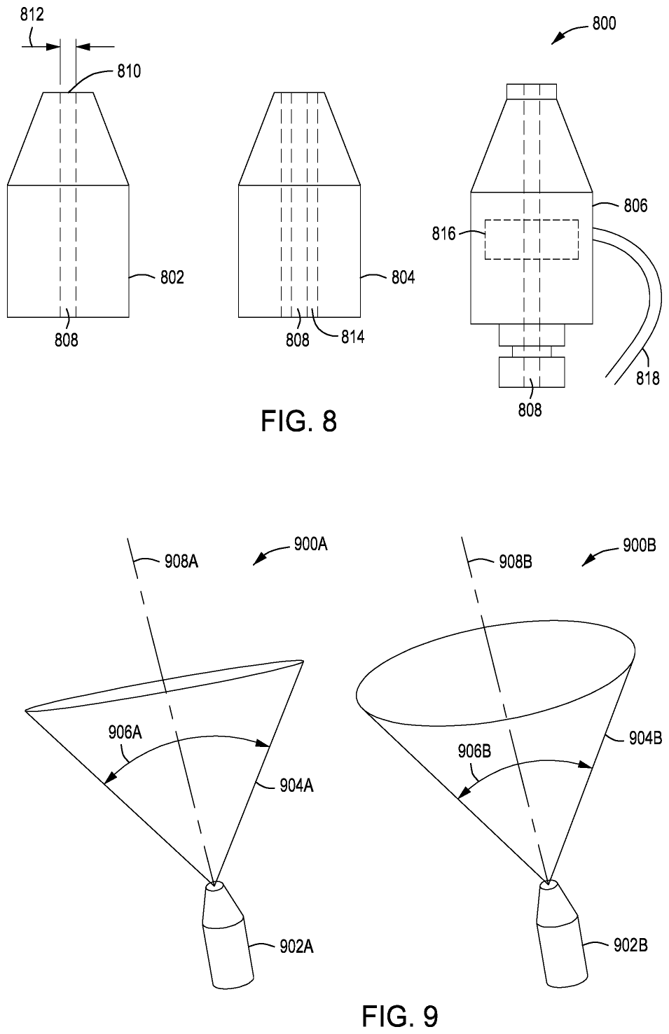

FIG. 8 illustrates cross-sectional views 800 of some spray nozzles 802, 804, 806 that are compatible with the spray apparatus. Other types of spray nozzles may also be compatible with some embodiments. A first version spray nozzle 802 may have an opening 810 supplied with fluid via fluid passage 808. A size 812 of the opening is selected to optimize the atomization and spray pattern. In some embodiments, the opening 810 may be approximately 1.0 mm. In some embodiments, the opening 810 may be approximately 0.5 mm. In some embodiments, the first version spray nozzle 802 may be used to atomize a fluid via pressure alone. In some embodiments, a second version spray nozzle 804 may have a fluid passage 808 that is surrounded by a gas passage 814 with a larger diameter than the diameter of the fluid passage 808. The gas and fluid may be provided through the second version spray nozzle 804 to provide atomization of the fluid at the spray nozzle opening. In some embodiments, the first version spray nozzle 802 and the second version spray nozzle 804 may be produced via a three-dimensional printing process. A third version spray nozzle 806 uses an ultrasonic or megasonic pulsing apparatus 816 to produce atomized spray. The ultrasonic or megasonic pulsing apparatus 816 is supplied with an energy source such as electrical power via wires 818. Fluid is passed through a fluid passage 808 and is energized by the ultrasonic or megasonic pulsing apparatus 816 as the fluid flows through the third version spray nozzle 806.

In some embodiments, the third version spray nozzle 806 may pulse at approximately 400 kHz to approximately 3 MHz. Ultrasonic or megasonic pulsing may affect particle sizes from approximately 0.1 μm to approximately 150 μm. In some embodiments, a plurality of spray nozzles may be used that include a mixture of two or more of the first version spray nozzle, the second version spray nozzle, and the third version spray nozzle. In some embodiments, the spray nozzle operates to deliver atomized fluid at approximately 30 psi to approximately 2500 psi. In some embodiments, the spray nozzle operates to deliver atomized fluid at approximately 1000 psi to approximately 1500 psi. In some embodiments, the spray nozzle operates to deliver atomized fluid at approximately 1000 psi to approximately 2500 psi. Higher atomized fluid pressures allow the atomized fluid to penetrate deeper into openings of the substrate surface to enhance the cleaning effect (e.g., removal of particles). In some embodiments, the spray nozzle operates in conjunction with a gas to deliver atomized fluid at approximately 30psi to approximately 500 psi. The gas enhances the atomization and allows atomization to occur at lower pressures. In some embodiments, the spray nozzle operates without a gas to deliver atomized fluid at approximately 500 psi to approximately 2500 psi. In some embodiments, the spray nozzle operates with a gas to deliver atomized fluid at approximately 500 psi to approximately 2500 psi. Higher pressure sprays may incorporate a gas to also enhance the substrate surface cleaning and/or to prevent oxidation of materials on the substrate surface.

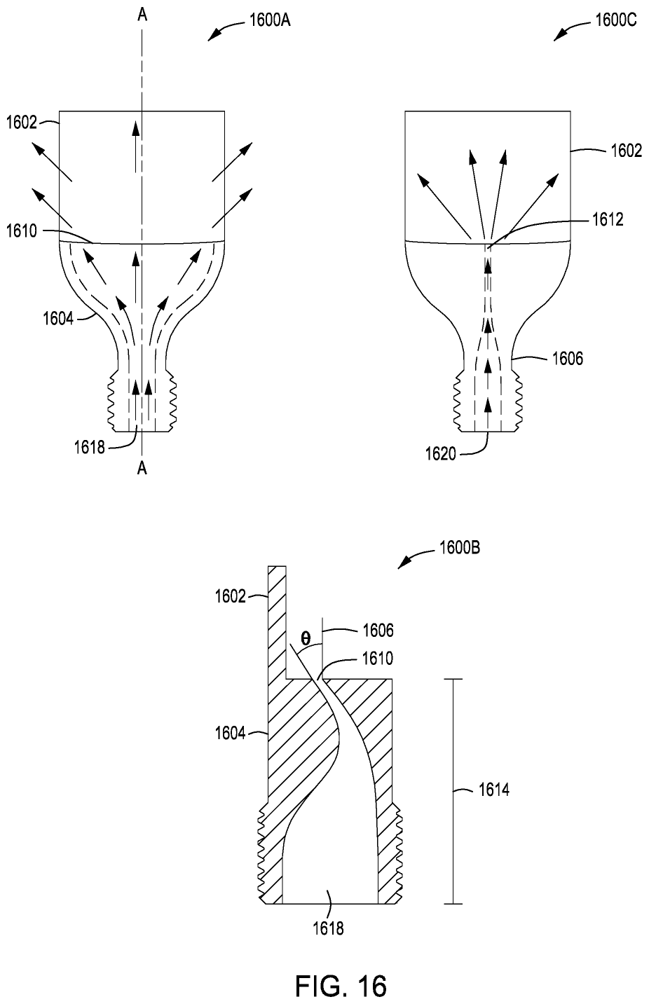

In some embodiments, as illustrated in FIG. 16, a deflector 1602 may be used in conjunction with spray nozzles 1604, 1606. In view 1600A, the spray nozzle 1604 has a spray nozzle outlet 1610 that contours into a knife-like opening such as a slit opening. In view 1600B, a side-view along A-A from view 1600A is shown. The spray nozzle inlet 1618 channels incoming fluid into a narrow slit, increasing pressure of the fluid, before releasing spray in the spray nozzle outlet 1610. In view 1600C, the spray nozzle 1606 has a spray nozzle outlet 1612 that contours into an opening such as, but not limited to, an oval and/or round opening. The spray nozzle inlet 1620 channels incoming fluid into a small opening, increasing pressure of the fluid, before releasing spray in the spray nozzle outlet 1612. As a spray outlet opening decreases, the spray angle changes. To create a fan-like spraying pattern, the deflector 1602 is added to the spray nozzles 1604, 1606 at a spray angle 1608 with respect to the spray nozzle outlet channels 1610, 1612. In some embodiments, the deflector 1602 is approximately perpendicular to a substrate surface to ensure maximum pressure is applied onto the substrate surface. The spray angle 1608 of the spray nozzle outlets 1610, 1612 may be customized and manufactured by an additive process (Additive Manufacturing—“AM”). With AM, a height 1614 of the spray nozzles 1604, 1606 may also be optimized and produced based on the spray angle 1608, fluid pressure, and/or distance between the spray nozzle outlets 1610, 1612 and a substrate surface.

FIG. 9 is a three-dimensional views 900A, 900B of spray patterns 904A, 904B of spray nozzles 902A, 902B that may be utilized in the spray apparatus. Centerlines 908A, 908B indicate the direction that the spray nozzles 902A, 902B are pointed in, respectively. In some embodiments, the spray patterns 904A, 904B are divergent. In some embodiments, the spray pattern 904A is divergent and fan-like in shape with an angular dispersion 906A of approximately 120 degrees. In some embodiments, the spray pattern 904B is divergent and conical in shape with an angular dispersion 906B of approximately 120 degrees. As indicated previously, the angular dispersions 906A, 906B may be adjusted based on the number of spray nozzles and/or to provide differing overlapping coverage to enhance a cleaning effect of the atomized fluid on the surface of a substrate. By overlapping the spray patterns of adjacent spray nozzles, more atomized fluid may be provided to the surface of the substrate to be cleaned, enhancing the cleaning effect.

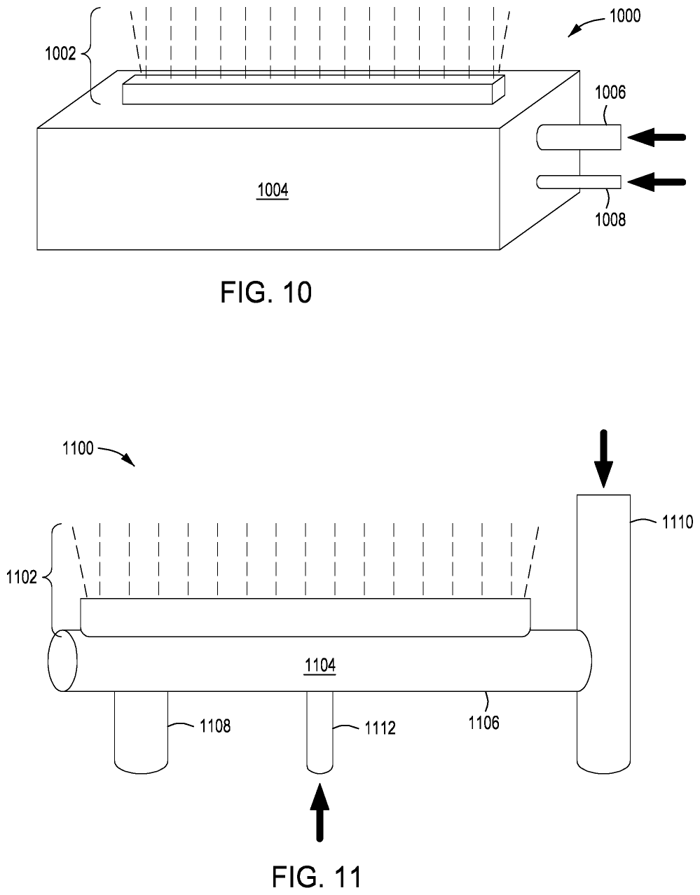

In FIG. 10, a three-dimensional view of a spray apparatus 1000 with a knife spray nozzle 1002 mounted on a spray manifold 1004 is illustrated. The knife spray nozzle 1002 has a slit opening that provides a sheet of atomized fluid to effectively spray and clean a substrate passing over the spray apparatus 1000. The sheet of atomized fluid spray allows cleaning of the surface of the substrate in an even and consistent manner. The substrate surface is impinged with atomized fluid at the same rate and pressure as the substrate moves across the spray apparatus. In some embodiments, the spray manifold is connected to a fluid supply line 1006 and/or a gas supply line 1008. The spray apparatus 1000 may atomize the fluid using gas and/or ultrasonic/megasonic pulsing apparatus and/or pressure alone. FIG. 11 depicts a three-dimensional view of a spray apparatus 1100 with a knife spray nozzle 1102 on a spray manifold 1104 with a cylindrical body 1106. In some embodiments, the spray apparatus 1100 may be supported by supports 1108, 1110. In some embodiments, a gas may be supplied to the spray manifold 1104 via a gas supply line 1112. In some embodiments, a fluid may be supplied to the spray manifold 1104 via a fluid supply line via support 1110.

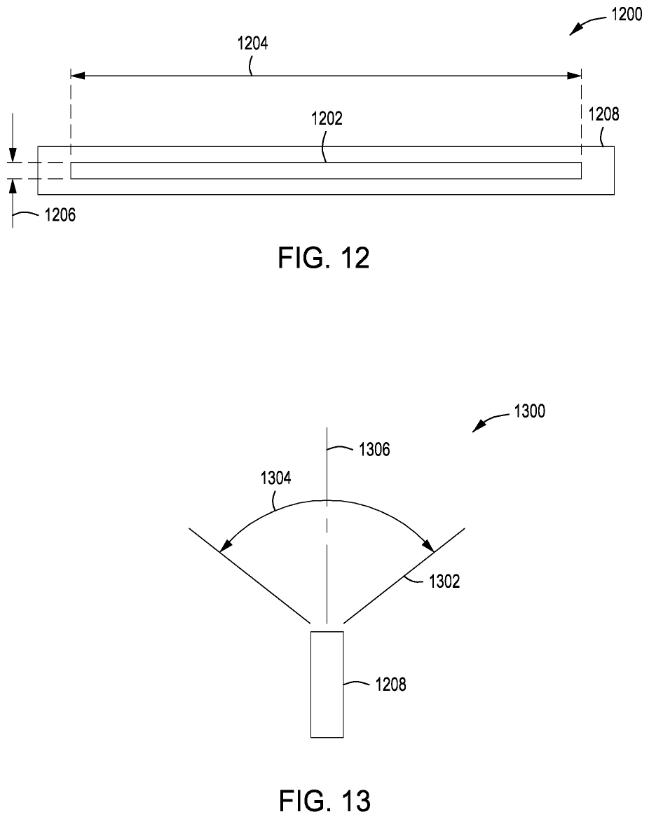

FIG. 12 is a top-down view 1200 of a knife spray nozzle 1208. The knife spray nozzle 1208 includes an opening 1202 that is longer than the opening 1202 is wide. A length 1204 may be adjusted to ensure full coverage of a surface to be cleaned on a substrate. For example, the length 1204 may coincide with an approximate diameter of a substrate (e.g., approximately 300mm, approximately 450mm, etc.). A width 1206 of the knife spray nozzle 1208 may be dependent on a pressure of a supplied fluid and/or gas. Adjustment of the width 1206 allows for adjustment of spray pressure and/or spray pattern. In FIG. 13, a cross-sectional view 1300 of a spray pattern 1302 of the knife spray nozzle 1208 is illustrated. A centerline 1306 indicates the direction that the knife spray nozzle 1208 is pointing in. In some embodiments, the spray pattern 1302 has a divergent spray pattern. In some embodiments, the spray pattern 1302 has a divergent spray pattern with an angular dispersion 1304 of approximately 120 degrees. The angular dispersion may be adjusted to adjust the pressure of the atomized fluid hitting the surface of the substrate passing over the spray apparatus and/or to increase/decrease the rate of atomized fluid hitting the surface of the substrate. For example, a wider angular dispersion 1304 would permit more atomized fluid to impinge the surface of the substrate but at a lesser pressure (e.g., lower pressure on more area). A narrower angular dispersion 1304 may be used to increase pressure of the atomized fluid that impinges the surface of the substrate. (e.g., higher pressure on less area).

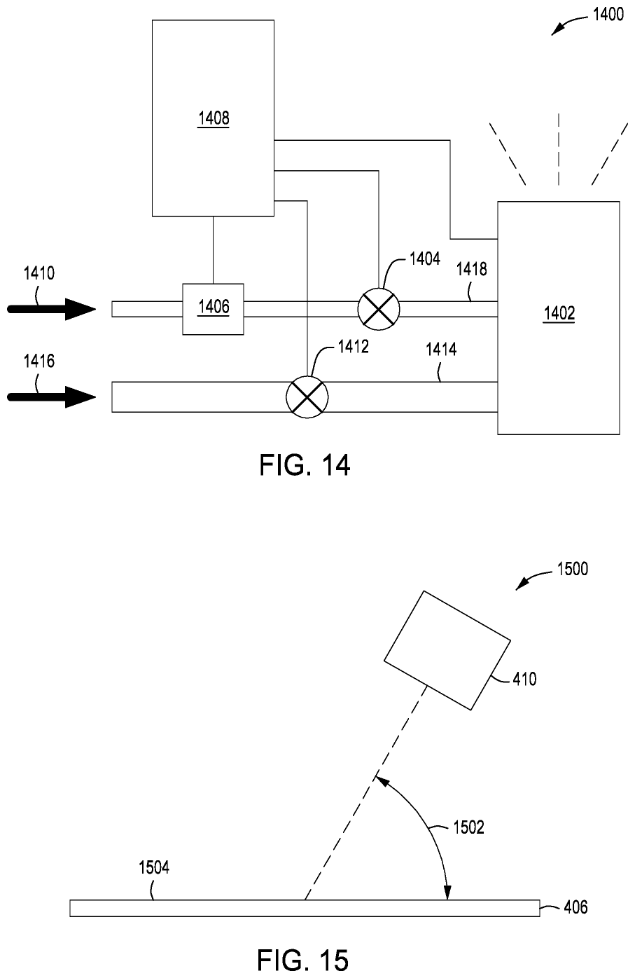

In FIG. 14, a cross-sectional view of a spray system 1400 is illustrated. In some embodiments, the spray system 1400 may include a spray apparatus 1402 with a fluid supply line 1414 that may have a fluid control valve 1412 to regulate the flow of the fluid 1416. In some embodiments, the spray system 1400 may also include a gas supply line 1418 with a gas control valve 1404 and a gas pressure regulator 1406 to control the flow of a gas 1410. In some embodiments, a controller 1408 may be used to regulate and control the gas pressure regulator 1406, the gas control valve 1404, the fluid control valve 1412, and/or the spray apparatus 1402. In some embodiments, the controller 1408 may receive feedback regarding materials on the surface of a substrate and/or a dimensional size of the substrate and adjust a gas, a fluid, a spray pattern, and/or a number of activated spray nozzles. In some embodiments, the controller 1408 may adjust spray, gas, and/or fluid parameters for the spray apparatus 1402 based on a type of abrasive used for polishing the surface of the substrate.

While the foregoing is directed to embodiments of the present principles, other and further embodiments of the principles may be devised without departing from the basic scope thereof.

1. An apparatus for removing particles from a substrate surface after a chemical mechanical polish, comprising:
a manifold configured to receive and atomize a fluid; and
at least one spray nozzle mounted to the manifold and configured to spray the atomized fluid in a divergent spray pattern such that the substrate surface is cleansed when impinged by spray from the at least one spray nozzle.

2. The apparatus of claim 1, wherein the at least one spray nozzle sprays the atomized fluid at a pressure of approximately 30 psi to approximately 2500 psi.

3. The apparatus of claim 1, wherein the at least one spray nozzle sprays the atomized fluid ata pressure of approximately 1000 psi to approximately 1500 psi.

4. The apparatus of claim 1, wherein the manifold further receives a gas to facilitate in atomizing the fluid.

5. The apparatus of claim 1, wherein the at least one spray nozzle has a spray opening of greater than zero to approximately 1 mm.

6. The apparatus of claim 1, wherein the at least one spray nozzle has a spray opening of greater than zero to approximately 0.5 mm.

7. The apparatus of claim 1, wherein the at least one spray nozzle has a fan-like or conical spray pattern.

8. The apparatus of claim 1, wherein the at least one spray nozzle has a spray pattern of less than or equal to approximately 120 degrees.

9. The apparatus of claim 1, wherein at least one of the at least one spray nozzle is a pulsed jet spray nozzle.

10. The apparatus of claim 9, wherein the pulsed jet spray nozzle is configured to operate at a frequency of approximately 400 kHz to approximately 3 MHz.

11. The apparatus of claim 1, wherein the at least one spray nozzle is a knife spray nozzle with a slit opening.

12. The apparatus of claim 11, wherein the knife spray nozzle has a length approximately equal to a diameter of a substrate.

13. An apparatus for removing particles from a substrate surface after a chemical mechanical polish, comprising:
a manifold that atomizes deionized (DI) water with nitrogen gas; and
at least one spray nozzle mounted to the manifold and configured to deliver the atomized DI water in a divergent spray pattern to cleanse the substrate surface when the substrate surface is impinged by spray from the at least one spray nozzle, wherein the at least one spray nozzle sprays the atomized fluid at a pressure of approximately 30 psi to approximately 2500 psi.

14. The apparatus of claim 13, wherein the at least one spray nozzle has a spray opening of greater than zero to approximately 1 mm with a fan-like or conical spray pattern of 120 degrees or less.

15. The apparatus of claim 13, wherein the at least one spray nozzle is a pulsed jet spray nozzle that is configured to operate at a frequency of approximately 400 kHz to approximately 3 MHz.

16. The apparatus of claim 13, wherein the at least one spray nozzle is a knife spray nozzle with a slit opening having a length of approximately a diameter of a substrate.

17. A system for chemical mechanical polishing of a substrate surface, comprising:
a plurality of platens for polishing substrates;
a plurality of spray apparatus for cleaning a surface of a substrate, the plurality of spray apparatus disposed between the plurality of platens,
wherein at least one of the plurality of spray apparatus includes a manifold configured to atomize deionized (DI) water with nitrogen gas and at least one spray nozzle mounted to the manifold and configured to deliver the atomized DI water in a divergent spray pattern to cleanse the substrate surface when the substrate surface is impinged by spray from the at least one spray nozzle, wherein the at least one spray nozzle sprays the atomized fluid at a pressure of approximately 30 psi to approximately 2500 psi; and
a controller that interacts with at least one of the spray apparatus to alter a spray pattern of the at least one spray nozzle based on a substrate size or material composition of the substrate surface.

18. The system of claim 17, wherein the at least one spray nozzle has a spray opening of greater than zero to approximately 1 mm with a fan-like or conical spray pattern of 120 degrees or less.

19. The system of claim 17, wherein the at least one spray nozzle is a pulsed jet spray nozzle that is configured to operate at a frequency of approximately 400 kHz to approximately 3 MHz.

20. The system of claim 17, wherein the at least one spray nozzle is a knife spray nozzle with a slit opening having a length of approximately a diameter of a substrate.
